(19) United States
(12) Patent Application Publication
(10) Pub. No.: US 2026/0233241 A1
(43) Pub. Date: Aug. 13, 2026

(54) METHOD FOR PRODUCING A BASE PLATE FOR A SEMICONDUCTOR MODULE

(71) Applicant: Infineon Technologies AG, Neubiberg (DE)

(72) Inventor: Xifang Liao, Soest (DE)

(21) Appl. No.: 19/529,677

(22) Filed: Feb. 4, 2026

(30) Foreign Application Priority Data
Feb. 13, 2025 (DE) 102025105504.1

(51) Int. Cl. B05B 7/24; B05B 7/02; B05B 7/08; C23C 24/04; H10P 76/40; H10W 90/00

(52) U.S. Cl. CPC B05B 7/2478; B05B 7/02; B05B 7/0815; C23C 24/04; H10P 76/4085; H10W 90/734

(57) ABSTRACT

A method includes: attaching a base plate to a lateral side of a rotatable disc; directing an outlet of a spray gun towards an edge of a surface of the base plate facing away from the disc; attaching a spacer mask to the disc and/or to the base plate such that the mask is arranged adjacent to the surface of the base plate and between the base plate and the spray gun, the mask including openings with a size and shape corresponding to a size and shape of a spacer to be formed on the base plate; rotating the disc at a constant rotation rate in a horizontal direction such that the base plate and mask repeatedly pass the outlet of the spray gun; and spraying particles of a first material on the mask and sections of the surface of the base plate visible through the openings in the mask.

### TECHNICAL FIELD

The instant disclosure relates to a method for producing a base plate for a semiconductor module, in particular for producing a base plate with a plurality of spacers arranged thereon.

### BACKGROUND

Power semiconductor module arrangements often include a base plate within a housing. At least one substrate is arranged on the base plate. A semiconductor arrangement including a plurality of controllable semiconductor elements (e.g., two IGBTs in a half-bridge configuration) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer is usually attached to the base plate by means of a solder layer or a sintering layer. When mounting a substrate to a base plate, e.g., by soldering or sintering techniques, the substrate is pressed on the base plate with a certain amount of force. This force may range from a very low force, such as that exerted by gravity, as in the case of pressureless soldering, to a very high pressing forces such as those required for many forms of sintering or diffusion soldering. In order to prevent a connection layer (e.g., solder layer or sinter layer) arranged between the substrate and the base plate from becoming too thin, a plurality of spacers may be arranged on the base plate, and between the base plate and the substrate. The spacers ensure that a thickness of the connection layer always equals at least a height of the spacers. The spacers generally may be separate elements or may be integrally formed with the base plate.

There is a need for a fast and cost-effective method for producing a base plate with spacers arranged thereon.

### SUMMARY

A method for forming a plurality of spacers on a base plate according to embodiments of the disclosure includes attaching a base plate for a semiconductor module to a lateral side of a rotatable disc, with a first surface of the base plate facing away from the rotatable disc, directing an outlet of a spray gun towards a first edge of the first surface of the base plate, attaching a spacer mask to the rotatable disc and/or to the base plate such that the spacer mask is arranged adjacent to the first surface of the base plate and between the base plate and the spray gun, the spacer mask including a plurality of openings, wherein a size and shape of each opening of the plurality of openings corresponds to a size and shape of a spacer to be formed on the base plate, rotating the rotatable disc with the base plate and the spacer mask attached thereto at a constant rotation rate in a horizontal direction such that the base plate and the spacer mask repeatedly pass the outlet of the spray gun, and spraying particles of a first material on the spacer mask and the sections of the first surface of the base plate visible through the openings in the spacer mask through the outlet of the spray gun, while moving the spray gun in a vertical direction from the first edge towards an opposite second edge of the first surface of the base plate, wherein the spray gun is moved from the first edge towards the opposite second edge of the first surface of the base plate at a constant speed.

A method for forming a plurality of spacers on a base plate according to further embodiments of the disclosure includes attaching a base plate for a semiconductor module to a lateral side of a rotatable disc, with a first surface of the base plate facing away from the rotatable disc, directing an outlet of a spray gun towards a first edge of the first surface of the base plate, rotating the rotatable disc with the base plate attached thereto at a constant rotation rate in a horizontal direction such that the first surface of the base plate repeatedly passes the outlet of the spray gun, and spraying particles of a first material on the first surface of the base plate through the outlet of the spray gun, wherein a plurality of hold positions are defined between the first edge and an opposite second edge of the first surface of the base plate, the spray gun moves successively from one hold position to the next hold position, wherein the spray gun stops at each hold position for a defined amount of time, and spraying particles of a first material on the first surface of the base plate through the outlet of the spray gun comprises spraying particles of a first material on the first surface of the base plate while the spray gun stops at each of the plurality of hold positions.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a power semiconductor module arrangement.

FIG. 2 is a cross-sectional view of another power semiconductor module arrangement with spacers arranged between a substrate and a base plate.

FIG. 3 schematically illustrates an arrangement for forming spacers on a base plate.

FIGS. 4A and 4B schematically illustrate top views of a base plate before (FIG. 4A) and after (FIG. 4B) forming a coating layer thereon.

FIG. 5 schematically illustrates a mask for forming a coating layer on a base plate.

FIGS. 6A and 6B schematically illustrate top views of a base plate with a coating layer before (FIG. 6A) and after (FIG. 6B) forming a plurality of spacers thereon, using a method according to embodiments of the disclosure.

FIGS. 7A and 7B schematically illustrate top views of a base plate without a coating layer before (FIG. 7A) and after (FIG. 7B) forming a plurality of spacers thereon.

FIG. 8 schematically illustrates a mask for forming a plurality of spacers on a base plate.

FIG. 9 schematically illustrates an arrangement for forming a plurality of spacers on a base plate.

FIGS. 10A and 10B schematically illustrate top views of a base plate without a coating layer before (FIG. 10A) and after (FIG. 10B) simultaneously forming a coating layer and a plurality of spacers thereon, using a method according to further embodiments of the disclosure.

FIGS. 11A and 11B schematically illustrate top views of a base plate with a coating layer before (FIG. 11A) and after (FIG. 11B) forming a plurality of spacers thereon, using a method according to further embodiments of the disclosure.

FIGS. 12A and 12B schematically illustrate top views of a base plate without a coating layer before (FIG. 12A) and after (FIG. 12B) forming a plurality of spacers thereon, using a method according to further embodiments of the disclosure.

FIG. 13 schematically illustrates in a cross-sectional view a base plate with a plurality of spacers formed thereon, using a method according to embodiments of the disclosure.

FIG. 14 schematically illustrates in a cross-sectional view a base plate with a plurality of spacers formed thereon, using a method according to further embodiments of the disclosure.

FIG. 15 schematically illustrates in a cross-sectional view a coating layer with a plurality of spacers formed thereon.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description as well as in the claims, designations of certain elements as “first element”, “second element”, “third element” etc. are not to be understood as enumerative. Instead, such designations serve solely to address different “elements”. That is, e.g., the existence of a “third element” does not necessarily require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connectable pads and includes at least one semiconductor element with electrodes.

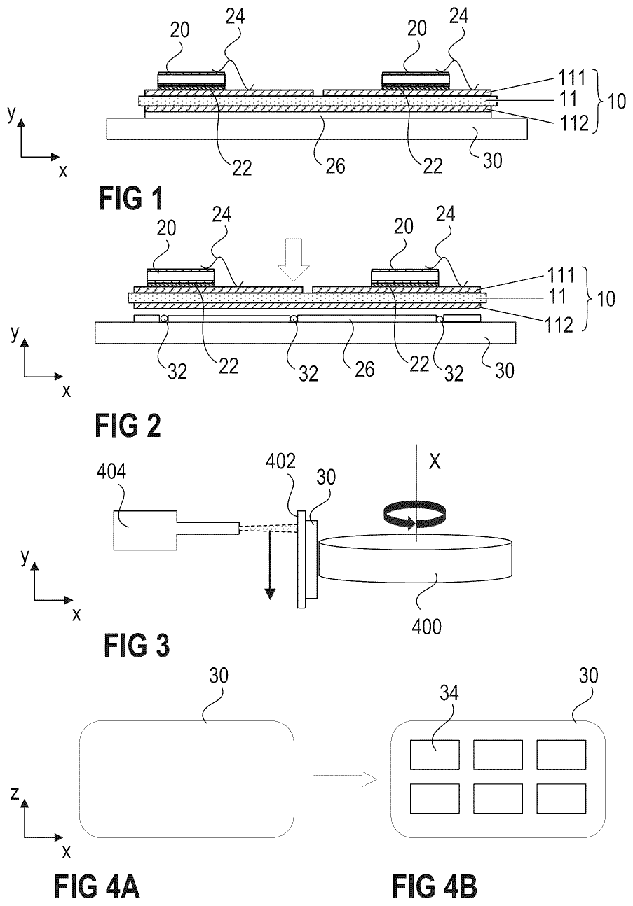

Referring to FIG. 1, a substrate 10 is schematically illustrated. The substrate 10 comprises, for example, a dielectric isolation layer 11, a (structured) first electrically conductive layer 111 and a (structured) second electrically conductive layer 112. The first electrically conductive layer 111 is arranged on a first side of the dielectric isolation layer 11 and the second electrically conductive layer 112 is arranged on a second side of the dielectric isolation layer 11 opposite the first side. The dielectric isolation layer 11 is thus arranged between the first electrically conductive layer 111 and the second electrically conductive layer 112. The second electrically conductive layer 112, however, is merely optional. It is likewise possible to arrange only the first electrically conductive layer 111 on the dielectric isolation layer 11 and to completely omit the second electrically conductive layer 112.

Each of the first electrically conductive layer 111 and the second electrically conductive layer 112 can consist of one of the following materials or comprise one of the following materials: copper, a copper alloy, aluminum; an aluminum alloy; any other metal or any other metal alloy which remains in a solid state during the operation of the power semiconductor module. The substrate 10 can be a ceramic substrate, that is to say a substrate in which the dielectric isolation layer 11 consists of ceramic. The dielectric isolation layer 11 can thus be a thin ceramic layer, for example. The ceramic of the dielectric isolation layer 11 can, for example, consist of one of the following materials or comprise one of the following materials: aluminum oxide; aluminum nitride; zirconium oxide; silicon nitride; boron nitride; or any other ceramic. By way of example, the dielectric isolation layer 11 can consist of one of the following materials or comprise one of the following materials: Al₂O₃, AlN, or Si₃N₄. The substrate 10 can be for example a so-called direct copper bonding (DCB) substrate, a direct aluminum bonding (DAB) substrate, an insulated metal substrate (IMS) or an active metal brazing (AMB) substrate. The substrate 10 can for example also be a conventional printed circuit board (PCB) with a non-ceramic dielectric isolation layer 11. A non-ceramic dielectric isolation layer 11 can for example consist of a cured resin or comprise a cured resin.

Still referring to FIG. 1, one or more semiconductor bodies 20 can be arranged on the substrate 10. Each of the semiconductor bodies 20 on the substrate 10 can comprise a diode, an IGBT (insulated gate bipolar transistor), a MOSFET (metal oxide semiconductor field effect transistor), a JFET (junction field effect transistor), an HEMT (high electron mobility transistor), or any other suitable controllable semiconductor component. The one or more semiconductor bodies 20 can form a semiconductor arrangement on the substrate 10. Only two semiconductor bodies 20 are illustrated by way of example in FIG. 1.

The first electrically conductive layer 111 illustrated in FIG. 1 is a structured layer. In this context, “structured layer” means that the first electrically conductive layer 111 is not a continuous layer, but rather has interruptions between different sections of the layer. Different semiconductor bodies 20 can be arranged on the same section or on different sections of the first electrically conductive layer 111. The different sections of the first electrically conductive layer 111 can either have no electrical connection among one another or can be electrically connected to one another, e.g. by means of bond wires. Each of the semiconductor bodies 20 can be electrically and mechanically connected to the substrate 10 by means of an electrically conductive connection layer 22. FIG. 1 shows by way of example a substrate 10 with connection layers 22 arranged thereon. Such an electrically conductive connection layer 22 can be, in principle, a solder layer, a layer composed of an electrically conductive adhesive or a layer composed of a sintered metal powder, e.g. a sintered silver powder.

In principle, however, the first electrically conductive layer 111 can also be a continuous layer. The second electrically conductive layer 112 (if present) can be either a continuous layer or likewise a structured layer.

In order to connect a semiconductor body 20 to the substrate 10, the semiconductor body 20 is arranged on the surface (upper surface) of the substrate 10, wherein the connection layer 22 is arranged between the substrate 10 and the semiconductor body 20. The upper surface of the substrate 10 is a surface of the first electrically conductive layer 111 which faces away from the dielectric isolation layer 11. Semiconductor bodies 20 can alternatively or additionally be connected to the substrate 10 for example also by means of bond wires 24.

The substrate 10 with the at least one semiconductor body 20 arranged thereon can, for example, be part of a power semiconductor module and be arranged in a package (not illustrated).

The substrate 10 is arranged on a baseplate 30. The baseplate 30 can be a metallic baseplate, for example. While a single substrate 10 is arranged on the baseplate 30 in FIG. 1, it is also possible, in principle, to arrange more than one substrate 10 on the same baseplate 30. A connection layer 26 is arranged between the substrate 10 and the baseplate 30. The connection layer 26 mechanically connects the substrate 10 and the baseplate 30 to one another. It is likewise possible for the connection layer 26 to produce an electrical connection between the substrate 10 and the baseplate 30. The connection layer 26 can be, for example, a solder layer, a layer composed of an electrically conductive adhesive or a layer composed of a sintered metal powder, e.g., a sintered silver powder.

The baseplate 30 can be arranged, for example, on a heat sink (not illustrated). Heat is generally generated during the operation of the semiconductor arrangement. The heat can be dissipated to a heat sink via the substrate 10, the connection layer 26 and the baseplate 30. Therefore, the connection layer 26 and the baseplate 30 generally have a good thermal conductivity.

In order to ensure firstly a stable mechanical connection between the substrate 10 and the baseplate 30 and secondly a good thermal conductivity, the connection layer 26 generally has a thickness which does not fall below a specific minimum thickness and does not exceed a specific maximum thickness.

As schematically illustrated in FIG. 2, in order to be able to set a thickness of the connection layer 26 in a targeted manner when connecting the substrate 10 to the baseplate 30, provision is often made of spacers 32 arranged between the baseplate 30 and the substrate 10. Such spacers 32 have, in a direction perpendicular to the upper (first) surface of the baseplate 30, a thickness corresponding to the desired thickness of the connection layer 26. In this case, the upper (first) surface of the baseplate 30 is the surface on which the at least one substrate 10 is arranged.

One or more spacers 32 may be arranged on the base plate 30, for example, before arranging the one or more substrates 10 and the respective connection layers 26 thereon. The substrate(s) 10 can then be placed or pressed onto the spacers 32. The interspace between the baseplate 30 and the substrate 10 can be completely filled by the connection layer 26. The (minimum) thickness of the connection layer 26 can thus be set in a simple manner. The spacers 32 may have any suitable form and may be arranged in any suitable positions on the base plate 30. Usually, as few spacers 82 as possible are used, in order to save material and, consequently, costs. According to one example, one spacer 32 is arranged below each corner of a rectangular or square substrate 10. When joining the substrate(s) 10 to the base plate 30 by means of the connection layers 26, the material forming the connection layers 26 initially is usually liquid or viscous. The liquid or viscous material of the connection layers 26 may be displaced in the horizontal directions x, z to a certain degree and the thickness of the connection layers 26 may decrease, at least in some areas. The spacers 32 prevent the substrate(s) 10 from moving closer to the base plate 30. The spacers 32 may remain between the substrate(s) 10 and the base plate 30 after mounting/joining the substrates 10 onto the base plate 30.

A method for forming a plurality of spacers 32 on a base plate 30 according to embodiments of the disclosure comprises attaching a base plate 30 for a semiconductor module to a lateral side of a rotatable disc 400, with a first surface of the base plate 30 facing away from the rotatable disc 400, and directing an outlet of a spray gun 404 towards a first edge of the first surface of the base plate 30. A spacer mask 402 is attached to the rotatable disc 400 and/or to the base plate 30 such that the spacer mask 402 is arranged adjacent to the first surface of the base plate 30 and between the base plate 30 and the spray gun 404. The spacer mask 402 comprises a plurality of openings 410, wherein a size and shape of each opening 410 of the plurality of openings 410 corresponds to a size and shape of a spacer 32 to be formed on the base plate 30. The rotatable disc 400 with the base plate 30 and the spacer mask 402 attached thereto is then rotated at a constant rotation rate in a horizontal direction (around a rotation axis X) such that the base plate 30 and the spacer mask 402 repeatedly pass the outlet of the spray gun 404. Particles of a first material are sprayed on the spacer mask 402 and the sections of the first surface of the base plate 30 visible through the openings 410 in the spacer mask 404 through the outlet of the spray gun 404, while moving the spray gun 404 in a vertical direction from the first edge towards an opposite second edge of the first surface of the base plate 30, wherein the spray gun 404 is moved from the first edge towards the opposite second edge of the first surface of the base plate 30 at a constant speed.

A base plate 30 attached to a rotatable disc 400, a spray gun 404 directed towards the base plate 30, and a spacer mask 402 arranged in front of the base plate 30 and between the base plate 30 and the spray gun 404 are schematically illustrated in FIG. 3. A rotation of the rotatable disc 400 around the rotation axis X is indicated by means of a circular arrow in FIG. 3. The movement of the spray gun 404 and the respective particle stream directed towards the spacer mask 402 and the base plate 30 is indicated by means of a vertical arrow in FIG. 3. In the example illustrated in FIG. 3, the spray gun 404 moves from an upper edge of the base plate 30 down towards the opposite lower edge. It is, however, also possible that the spray gun 404 instead moves in an upward direction from the lower edge towards the upper edge. A spacer mask 402 according to embodiments of the disclosure is schematically illustrated in FIG. 8.

The base plate 30 may consist of a solderable material such as, e.g., copper. In this case, spacers 32 may be formed directly on the first surface of the base plate 30. Spraying particles of a first material on the first surface of the base plate 30 through the outlet of the spray gun 404 may comprise spraying copper particles on the first surface of the base plate 30 through the outlet of the spray gun 404, for example. That is, copper spacers 32 may be formed on a copper base plate 30, for example.

Some base plates 30, however, do not consist of a solderable material. For example, some base plates 30 consist of AlSiC. If a base plate 30 does not consist of a solderable material, it is not possible to directly attach a substrate 10 thereto by means of a connection layer 26. If this is the case, a coating layer 34 may first be formed on the base plate 30. The coating layer 34 consist of a solderable material. In this way, it is possible to attach a substrate 10 to the base plate 30, with the coating layer 34 arranged between the substrate 10 and the base plate 30, and, in particular, between the connection layer 26 and the base plate 30. The plurality of spacers 32 in such a case is not formed directly on the base plate 30, but on the coating layer 34 instead.

That is, if the base plate 30 does not consist of a solderable material, the method may further comprise, before attaching the spacer mask 402 to the rotatable disc 400 and/or to the base plate 30, attaching a coating mask 406 to the rotatable disc 400 and/or to the base plate 30 such that the coating mask 406 is arranged adjacent to the first surface of the base plate 30 and between the base plate 30 and the spray gun 404. The coating mask 406 comprises one or more openings 412, wherein a size and shape of each opening 412 of the one or more openings 412 corresponds to a size and shape of a coating layer 34 to be formed on the base plate 30. The method further comprises rotating the rotatable disc 400 with the base plate 30 and the coating mask 406 attached thereto at a constant rotation rate in the horizontal direction (around the rotation axis X) such that the base plate 30 and the coating mask 406 repeatedly pass the outlet of the spray gun 404, spraying particles of the first material on the coating mask 406 and the sections of the first surface of the base plate 30 visible through the openings 412 in the coating mask 406 through the outlet of the spray gun 404, while moving the spray gun 404 in the vertical direction from the first edge towards the second edge of the first surface of the base plate 30, wherein the spray gun 404 is moved from the first edge towards the second edge at a constant speed. Once the coating layer 34 has been formed, the coating mask 406 can be removed.

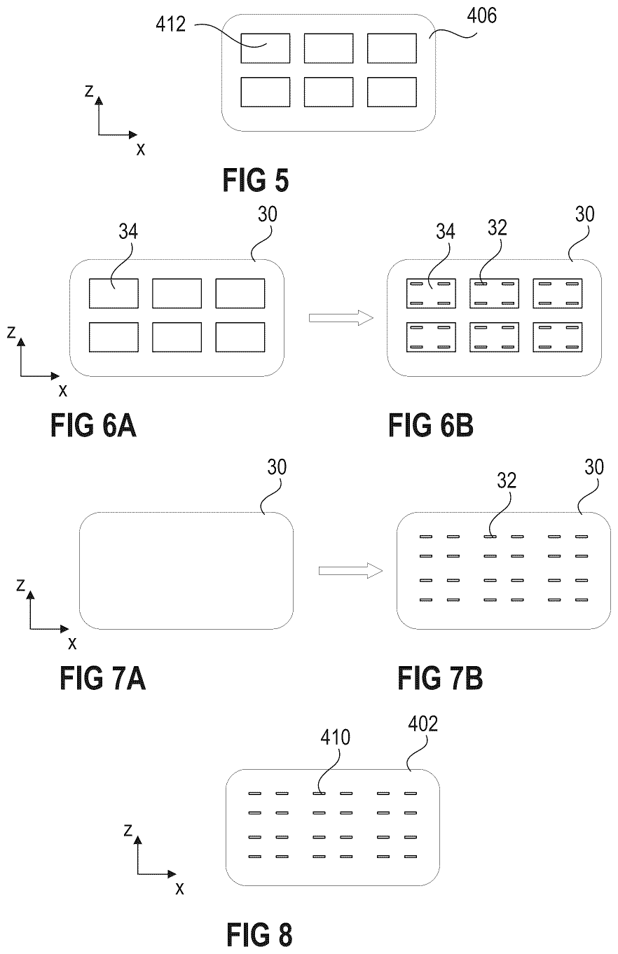

That is, the coating layer 34 is first formed using a first mask (the coating mask 406), and only then the plurality of spacers 32 are formed using a second mask (the spacer mask 402) that is different from the first mask. The resulting coating layer 34 may comprise one or more sections. FIGS. 4A and 4B schematically illustrate top views of a base plate before (FIG. 4A) and after (FIG. 4B) forming a coating layer 34 thereon. In the example illustrated in FIGS. 4A and 4B, the coating layer 34 comprises a plurality of different sections. The number of sections of the coating layer 34 may correspond to the number of substrates 10 that are to be attached to the base plate 30. That is, if only one substrate 10 is to be attached to the base plate 30, a continuous coating layer 34 may be formed on the base plate 30 (coating layer comprises only one continuous section). However, it is also contemplated that a single, large continuous coating layer 34 could also be used where multiple substrates 10 are to be attached to the base plate 30. In the example illustrated in FIG. 4B, the coating layer 34 comprises six separate sections. That is, six individual substrates 10 may be attached to the base plate 30. A respective coating mask 406 is schematically illustrated in FIG. 5. That is, in this example, the coating mask 406 comprises six openings 412. The coating layer 34 generally covers large parts of the base plate 30. For example, the coating layer 34 may cover at least 40% or at least 50% of the first surface of the base plate 30. The spacers 32, on the other hand, are generally comparably small as compared to the size of the base plate 30. For example, the plurality of spacers 32 may cover less than 20% or even less than 10% of the first surface of the base plate 30.

FIGS. 6A and 6B schematically illustrate top views of a base plate 30 with a coating layer 34 before (FIG. 6A) and after (FIG. 6B) forming a plurality of spacers 32 thereon, using a method according to embodiments of the disclosure. FIGS. 7A and 7B schematically illustrate top views of a base plate 30 without a coating layer 34 before (FIG. 7A) and after (FIG. 7B) forming a plurality of spacers thereon, using a method according to embodiments of the disclosure.

The spacers in FIGS. 6B and 7B have a rectangular cross-section and extend in parallel to the first edge and the second edge of the base plate 30. This, however, is only an example. Generally, the spacers 32 may have any suitable cross-section such as, e.g., a rounded or a square cross-section. Any other cross-sections are also possible. According to one example, the spacers 32 have an elongated form, similar to what is exemplarily illustrated in FIGS. 6B and 7B. That is, a length of a spacer 32 in a first horizontal direction x may be significantly larger than a width of the spacer 32 in a second horizontal direction z perpendicular to the first horizontal direction x. For example, one spacer 32 may extend along at least 50%, at least 75%, or even at least 90% of the length or width of a substrate 10, when the substrate 10 is attached to the base plate 30. The number of spacers 32 as well as their shape and dimensions may depend on the size and shape of the respective substrate 10, for example.

Using a spacer mask 402 for forming the plurality of spacers 32 on the base plate 30, however, is only an example. A method for forming a plurality of spacers 32 on a base plate 30 according to further embodiments of the disclosure comprises attaching a base plate 30 for a semiconductor module to a lateral side of a rotatable disc 400, with a first surface of the base plate 30 facing away from the rotatable disc 400, directing an outlet of a spray gun 404 towards a first edge of the first surface of the base plate 30, rotating the rotatable disc 400 with the base plate 30 attached thereto at a constant rotation rate in a horizontal direction such that the first surface of the base plate 30 repeatedly passes the outlet of the spray gun 404, and spraying particles of a first material on the first surface of the base plate 30 through the outlet of the spray gun 404. A plurality of hold positions are defined between the first edge and the opposite second edge of the first surface of the base plate 30. The spray gun 404 moves successively from one hold position to the next hold position, wherein the spray gun 404 stops at each hold position for a defined amount of time, and spraying particles of a first material on the first surface of the base plate 30 through the outlet of the spray gun 404 comprises spraying particles of a first material on the first surface of the base plate 30 while the spray gun 404 stops at each of the plurality of hold positions.

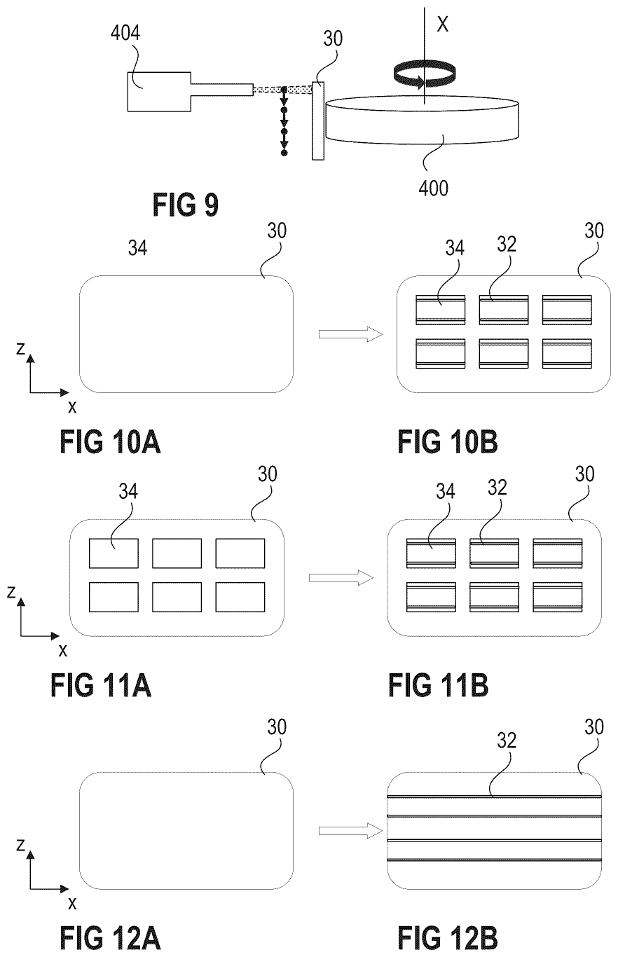

This is schematically illustrated in FIG. 9, wherein the hold positions are illustrated as black dots along the motion path of the spray gun 404. At each hold position the spray gun 404 may stop long enough to form a spacer 32 having a defined height/thickness in a direction perpendicular to the first surface of the base plate 30. If the spacers 32 are formed directly on the first surface of the base plate 30, and no mask is used at all while forming the spacers 32, this results in continuous spacers 32 extending from a third edge to an opposite fourth edge of the first surface of the base plate 30, wherein the third edge and the fourth edge are perpendicular to the first edge and the second edge. This is schematically illustrated in FIGS. 12A and 12B, which schematically illustrate top views of a base plate 30 without a coating layer 34 before (FIG. 12A) and after (FIG. 12B) forming a plurality of continuous spacers 32 thereon.

If a coating layer 34 is required on the first surface of the base plate 30, and between the base plate 30 and the plurality of spacers 32, the method may further comprise, before rotating the rotatable disc 400 with the base plate 30 attached thereto, attaching a coating mask 406 to the rotatable disc 400 and/or to the base plate 30 such that the coating mask 406 is arranged adjacent to the first surface of the base plate 30 and between the base plate 30 and the spray gun 404, the coating mask 406 comprising a plurality of openings 412, wherein a size and shape of each opening 412 of the plurality of openings 412 corresponds to a size and shape of a coating layer 34 to be formed on the base plate 30, and between the base plate 30 and the plurality of spacers 32.

According to some embodiment, the spray gun 404 may move from one hold position to the next hold position at a constant speed, and spraying particles of the first material on the first surface of the base plate 30 through the outlet of the spray gun 404 may further comprise spraying particles of the first material on the first surface of the base plate 30 while the spray gun 404 moves from one hold position to the next hold position. In this way, the coating layer 34 and the plurality of spacers 32 can be formed simultaneously. In particular, particles of the first material are sprayed on the first surface of the base plate 30 while moving the spray gun 404 from one hold position to the next hold position at a constant speed, thereby forming portions of the coating layer 34 having a defined thickness. The spray gun 404 stops at each hold position for a defined amount of time, resulting in a thickness of the material deposited on the base plate 30 which is greater than the thickness of the layer in the areas between the hold positions, thereby forming the spacers 32.

Alternatively, the coating layer 34 and the plurality of spacers 32 can be formed successively in two separate steps. That is, before rotating the rotatable disc 400 with the base plate 30 attached thereto, a coating mask 406 may be attached to the rotatable disc 400 and/or to the base plate 30 such that the coating mask 406 is arranged adjacent to the first surface of the base plate 30 and between the base plate 30 and the spray gun 404, the coating mask 406 comprising a plurality of openings 412, wherein a size and shape of each opening 412 of the plurality of openings 412 corresponds to a size and shape of a coating layer 34 to be formed on the base plate 30, and between the base plate 30 and the plurality of spacers 32. Before moving the spray gun 404 successively from one hold position to the next hold position, and spraying particles of the first material on the first surface of the base plate 30 through the outlet of the spray gun 404 while the spray gun 404 stops at each of the plurality of hold positions, the rotatable disc 400 with the base plate 30 and the coating mask 406 attached thereto may be rotated at a constant rotation rate such that the base plate 30 and the coating mask 406 repeatedly pass the outlet of the spray gun 404, particles of the first material may be sprayed on the coating mask 406 and the sections of the first surface of the base plate 30 visible through the openings 412 in the coating mask 406 through the outlet of the spray gun 404, while moving the spray gun 404 in a vertical direction from the first edge towards the second edge of the first surface of the base plate 30, wherein the spray gun 404 moves from the first edge towards the second edge of the first surface of the base plate 30 at a constant speed. In this way, a coating layer 34 having a constant thickness is formed. The outlet of the spray gun 404 is then directed towards the first edge of the first surface of the base plate 30 again. The plurality of spacers 32 are then formed in a separate subsequent step by moving the spray gun 404 from one hold position to the next hold position, and spraying particles of the first material on the first surface of the base plate 30 through the outlet of the spray gun 404 while the spray gun 404 stops at each hold position. When forming the plurality of spacers 32 in a separate step, no particles of the first material are sprayed on the first surface of the base plate 30 while the spray gun 404 moves from one hold position to the next hold position.

FIGS. 10A and 10B schematically illustrate top views of a base plate 30 without a coating layer 34 before (FIG. 10A) and after (FIG. 10B) simultaneously forming a coating layer 34 and a plurality of spacers 32 thereon. FIGS. 11A and 11B schematically illustrate top views of a base plate with a coating layer before (FIG. 11A) and after (FIG. 11B) forming a plurality of spacers thereon.

The methods according to the embodiments described herein may comprise spraying copper particles on the first surface of the base plate 30 through the outlet of the spray gun 404. According to some examples, spraying particles of the first material on the first surface of the base plate 30 through the outlet of the spray gun 404 may comprise a cold gas spraying process.

A maximum thickness d32 of each spacer 32 of the plurality of spacers 32 in a direction perpendicular to the first surface of the base plate 30 generally depends on at least one of a temperature at which the spraying is performed, a pressure at which the spraying is performed, the number of times the spraying is performed, a distance between the outlet of the spray gun 404 and the first surface of the base plate 30, when the first surface of the base plate 30 is perpendicular to a direction of a particle beam emitted by the spray gun 404, a powder feed rate supplied to the spray gun 404, and a relative velocity between the spray gun 404 and the rotatable disc 400 when the rotatable disc 400 is rotated at a constant rotation rate. That is, when forming each spacer 32 of the plurality of spacers 32, at least one of the mentioned parameters of the spraying process may differ from the respective parameter used when forming the coating layer 34.

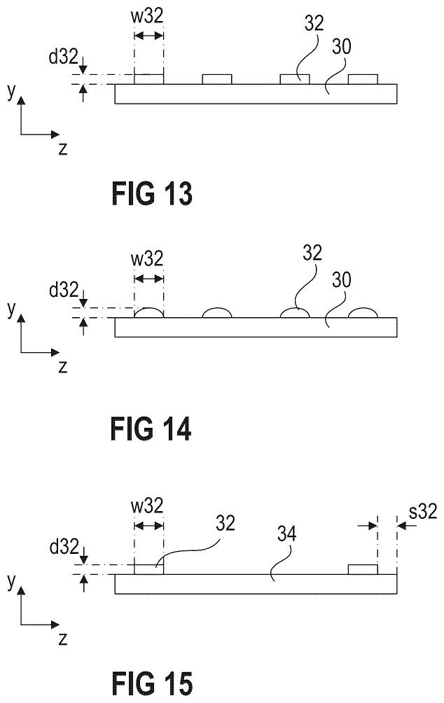

Generally, when a spacer mask 402 is used to form the plurality of spacers 32, the spacers 32 have a constant thickness d32 in a direction perpendicular to the first surface of the base plate 30. This is, because the edges of the resulting spacers 32 are defined by the side surfaces of the openings 410 in the spacer mask 402. This is schematically illustrated in the cross-sectional view of FIG. 13. When no spacer mask is used to form the plurality of spacers 32, the spacers generally have a varying thickness d32 in a direction perpendicular to the first surface of the base plate 30. This is, because if no spacer mask 402 is used, the thickness of the resulting spacers 32 follows a Gaussian distribution of the particles on the first surface of the base plate 30, or on the coating layer 34. This is schematically illustrated in the cross-sectional view of FIG. 14. Generally, a maximum thickness d32 of each spacer 32 of the plurality of spacers 32 may be in the range of 100 μm to 500 μm, for example. A maximum width w32 of each spacer 32 of the plurality of spacers 32 may be in the range of 1 mm to 5 mm, for example.

Now referring to FIG. 15, a distance s32 between an edge of a coating layer 34 and a spacer 32 that is arranged closest to the respective edge may be between 1 mm and 10 mm, for example. In this way, the distance s32 is large enough to ensure that the substrate 10, i.e. the second electrically conductive layer 112 of the substrate 10, that is to be mounted on the coating layer 34, comes to rest on the spacers 32. At the same time, the distance s32 is short enough in order to avoid an unintentional tilting of the substrate 10 that is mounted on the respective spacers 32.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for forming a plurality of spacers on a base plate, the method comprising:
attaching a base plate for a semiconductor module to a lateral side of a rotatable disc, with a first surface of the base plate facing away from the rotatable disc;
directing an outlet of a spray gun towards a first edge of the first surface of the base plate;
attaching a spacer mask to the rotatable disc and/or to the base plate such that the spacer mask is arranged adjacent to the first surface of the base plate and between the base plate and the spray gun, the spacer mask comprising a plurality of openings, wherein a size and shape of each opening of the plurality of openings corresponds to a size and shape of a spacer to be formed on the base plate;
rotating the rotatable disc with the base plate and the spacer mask attached thereto at a constant rotation rate in a horizontal direction such that the base plate and the spacer mask repeatedly pass the outlet of the spray gun; and
spraying particles of a first material on the spacer mask and sections of the first surface of the base plate visible through the openings in the spacer mask through the outlet of the spray gun, while moving the spray gun in a vertical direction from the first edge towards an opposite second edge of the first surface of the base plate, wherein the spray gun is moved from the first edge towards the opposite second edge of the first surface of the base plate at a constant speed.

2. The method of claim 1, further comprising:
before attaching the spacer mask to the rotatable disc and/or to the base plate, attaching a coating mask to the rotatable disc and/or to the base plate such that the coating mask is arranged adjacent to the first surface of the base plate and between the base plate and the spray gun, the coating mask comprising a plurality of openings, wherein a size and shape of each opening of the plurality of openings corresponds to a size and shape of a coating layer to be formed on the base plate;
rotating the rotatable disc with the base plate and the coating mask attached thereto at a constant rotation rate in the horizontal direction such that the base plate and the coating mask repeatedly pass the outlet of the spray gun;
spraying particles of the first material on the spacer mask and the sections of the first surface of the base plate visible through the openings in the coating mask through the outlet of the spray gun, while moving the spray gun in the vertical direction from the first edge towards the second edge of the first surface of the base plate, wherein the spray gun is moved from the first edge towards the second edge at a constant speed; and
removing the coating mask.

3. The method of claim 1, wherein the spraying of the particles of the first material comprises spraying copper particles.

4. The method of claim 1, wherein the spraying of the particles of the first material comprises a cold gas spraying process.

5. The method of claim 1, wherein in a direction perpendicular to the first surface of the base plate, a maximum thickness of each spacer of the plurality of spacers to be formed on the base plate depends on at least one of:
a temperature at which the spraying is performed;
a pressure at which the spraying is performed;
a distance between the outlet of the spray gun and the first surface of the base plate, when the first surface of the base plate is perpendicular to a direction of a particle beam emitted by the spray gun;
a powder feed rate supplied to the spray gun; and
a relative velocity between the spray gun and the rotatable disc when the rotatable disc is rotated at a constant rotation rate.

6. A method for forming a plurality of spacers on a base plate, the method comprising:
attaching a base plate for a semiconductor module to a lateral side of a rotatable disc, with a first surface of the base plate facing away from the rotatable disc;
directing an outlet of a spray gun towards a first edge of the first surface of the base plate;
rotating the rotatable disc with the base plate attached thereto at a constant rotation rate in a horizontal direction such that the first surface of the base plate repeatedly passes the outlet of the spray gun; and
spraying particles of a first material on the first surface of the base plate through the outlet of the spray gun,
wherein a plurality of hold positions are defined between the first edge and an opposite second edge of the first surface of the base plate,
wherein the spray gun moves successively from one hold position to the next hold position,
wherein the spray gun stops at each hold position for a defined amount of time, and
wherein spraying particles of the first material on the first surface of the base plate through the outlet of the spray gun comprises spraying particles of the first material on the first surface of the base plate while the spray gun stops at each of the plurality of hold positions.

7. The method of claim 6, further comprising:
before rotating the rotatable disc with the base plate attached thereto, attaching a coating mask to the rotatable disc and/or to the base plate such that the coating mask is arranged adjacent to the first surface of the base plate and between the base plate and the spray gun, the coating mask comprising a plurality of openings, wherein a size and shape of each opening of the plurality of openings corresponds to a size and shape of a coating layer to be formed on the base plate, and between the base plate and the plurality of spacers.

8. The method of claim 7, wherein the spray gun moves from one hold position to the next hold position at a constant speed, and wherein spraying particles of the first material on the first surface of the base plate through the outlet of the spray gun further comprises spraying particles of the first material on the first surface of the base plate while the spray gun moves from one hold position to the next hold position.

9. The method of claim 7, further comprising:
before moving the spray gun successively from one hold position to the next hold position, spraying particles of the first material on the first surface of the base plate through the outlet of the spray gun while the spray gun stops at each of the plurality of hold positions;
rotating the rotatable disc with the base plate and the coating mask attached thereto at the constant rotation rate such that the base plate and the coating mask repeatedly pass the outlet of the spray gun;
spraying particles of the first material on the coating mask and the sections of the first surface of the base plate visible through the openings in the coating mask through the outlet of the spray gun, while moving the spray gun in a vertical direction from the first edge towards the second edge of the first surface of the base plate, wherein the spray gun moves from the first edge towards the second edge of the first surface of the base plate at a constant speed; and
directing the outlet of the spray gun towards the first edge of the first surface of the base plate again.

10. The method of claim 6, wherein spraying particles of the first material on the first surface of the base plate through the outlet of the spray gun comprises spraying copper particles on the first surface of the base plate through the outlet of the spray gun.

11. The method of claim 6, wherein spraying particles of the first material on the first surface of the base plate through the outlet of the spray gun comprises a cold gas spraying process.

12. The method of claim 6, wherein a maximum thickness of each spacer of the plurality of spacers in a direction perpendicular to the first surface of the base plate depends on at least one of:
a temperature at which the spraying is performed;
a pressure at which the spraying is performed;
a distance between the outlet of the spray gun and the first surface of the base plate, when the first surface of the base plate is perpendicular to a direction of a particle beam emitted by the spray gun;
a powder feed rate supplied to the spray gun; and
a relative velocity between the spray gun and the rotatable disc when the rotatable disc is rotated at a constant rotation rate.
